(19) United States
(12) Patent Application Publication
(10) Pub. No.: US 2025/0151353 A1
(43) Pub. Date: May 8, 2025

(54) SEMICONDUCTOR DEVICE AND FORMATION METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Chao-Hsin Wu, Taipei City (TW); Yu Ting Chao, Kaohsiung City (TW); Yu-Hsuan Lu, Taichung City (TW); Ying-Chuan Chen, Tainan City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/501,960

(22) Filed: Nov. 3, 2023

(51) Int. Cl. H01L 29/18; H01L 21/02

(52) U.S. Cl. CPC H10D 62/84; H01L 21/02483; H01L 21/02565

(57) ABSTRACT

A method of forming a semiconductor device includes the following steps. A 2D material layer is formed over a bottom metal layer. A top metal layer is formed over the 2D material layer. An oxidation treatment is performed to the 2D material layer to form an oxide region interfacing both the 2D material layer and the top metal layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 2A and 3A are top views of a semiconductor device in various stages of fabrication in accordance with some embodiments of the present disclosure.

FIGS. 1B, 2B and 3B are cross-sectional views cut along line A-A′ of FIGS. 1A, 2A, and 3A, respectively.

FIG. 4 is a schematic reaction of the oxidation treatment in accordance with some embodiments.

FIGS. 5A-5B are cross-sectional views of a semiconductor device in various stages of fabrication in accordance with some embodiments of the present disclosure.

FIGS. 6A-6C are cross-sectional views of a semiconductor device in various stages of fabrication in accordance with some embodiments of the present disclosure.

FIGS. 7A and 8A are top views of a semiconductor device in various stages of fabrication in accordance with some embodiments of the present disclosure.

FIGS. 7B and 8B are cross-sectional views cut along line A-A′ of FIGS. 7A and 8A, respectively.

FIGS. 9A, 10A, 11A and 12A are top views of a semiconductor device in various stages of fabrication in accordance with some embodiments of the present disclosure.

FIGS. 9B, 10B, 11B and 12B are cross-sectional views cut along line A-A′ of FIGS. 9A, 10A, 11A and 12A, respectively.

FIGS. 13A and 14A are perspective views of a semiconductor device in various stages of fabrication in accordance with some embodiments of the present disclosure.

FIGS. 13B and 14B are top views of the semiconductor device.

FIGS. 13C and 14C are cross-sectional views cutting along line II-II′ in FIGS. 13A and 14A, respectively.

FIGS. 13D and 14D are cross-sectional views cutting along line I-I′ in FIGS. 13A and 14A, respectively.

FIG. 14E is a top view cutting along line III-III′ in FIG. 14A.

FIGS. 15 and 16A are cross-sectional views of the semiconductor device in various stages of fabrication in accordance with some embodiments of the present disclosure.

FIG. 16B illustrates an equivalent circuit diagram of the semiconductor device illustrated in FIG. 16A.

FIG. 16C is a cross-sectional view of a semiconductor device in various stages of fabrication in accordance with some embodiments of the present disclosure.

FIG. 16D is a cross-sectional view of a semiconductor device in various stages of fabrication in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

In an integrated circuit (IC) application, 2D materials have special structures and transport properties. For example, conductive channels made by the 2D materials can be turned on by applying suitable gate voltages. A semiconductor device may include a dielectric material which functions as a gate dielectric layer or a variable resistive dielectric layer. After a dielectric material is deposited over a film such as the 2D material layer or over a substrate, the dielectric material may be patterned using masking and etching processes to achieve a desired pattern. However, surfaces formed by such masking and etching processes are not uniform enough.

The present disclosure provides a method of forming an oxide region by oxidizing the 2D material layer. No additional masking and etching steps are required, and the oxide region can have a uniform surface as compared to being formed by masking and etching steps.

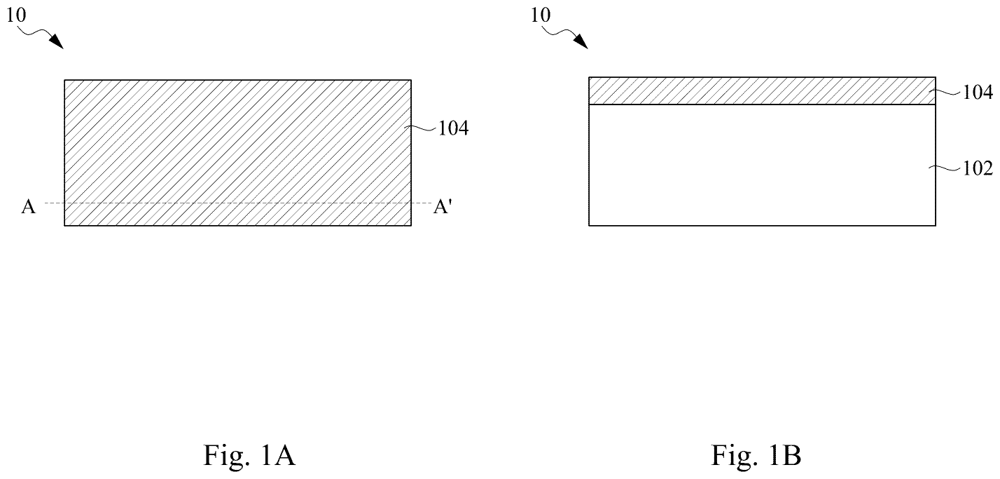

FIGS. 1A, 2A and 3A are top views of a semiconductor device 10 in various stages of fabrication in accordance with some embodiments of the present disclosure. FIGS. 1B, 2B and 3B are cross-sectional views cut along line A-A′ of FIGS. 1A, 2A, and 3A, respectively. Reference is made to FIGS. 1A and 1B. A two-dimensional (2D) material layer 102 is provided. In some embodiments, the 2D material layer 102 includes 2D materials with a semiconductor property. For example, the 2D material layer 102 may include transition metal dichalcogenide (TMD) monolayers, the TMD monolayers include molybdenum disulfide (MoS₂), tungsten disulfide (WS₂), tungsten diselenide (WSe₂), or the like. In some embodiments, the 2D material layer 102 may be formed on a first substrate (not shown), using a suitable method. For example, the 2D material layer 102 may be formed by micromechanical exfoliation and coupled over the first substrate or by sulfurization of a pre-deposited molybdenum (Mo) film or tungsten (W) film over the first substrate. In alternative embodiments, the TMD monolayers may be formed by micromechanical exfoliation and coupled over the first substrate, or by sulfidation of a pre-deposited tungsten (W) film over the first substrate using thermally cracked S molecules.

In some other embodiments where WS₂ is formed by micromechanical exfoliation, the 2D material layer 102 is formed on another substrate (not shown), such as a second substrate configured as a carrier substrate, and then transferred to the first substrate. For example, a 2D material film is formed on the second substrate by CVD, sputtering or ALD in some embodiments. A polymer film, such as poly(methyl methacrylate) (PMMA), is subsequently formed on the 2D material film. After forming the polymer film, the sample is heated, such as by placing the sample on a hot plate. Subsequent to heating, a corner of the 2D material film is peeled off the second substrate, such as by using a tweezers, and the sample is submerged in a solution to facilitate the separation of the 2D material film from the second substrate. The 2D material film and the polymer film are transferred to the first substrate. The polymer film is then removed from the 2D material film using a suitable solvent. In some embodiments, after the 2D material layer 102 is formed, the underlying first substrate is removed.

In some embodiments, a metal layer 104 is formed over the 2D material layer 102. In certain embodiments, the metal layer 104 may include a metal with a high electron affinity, such as Au, Ag, Pt, the like, or a combination thereof. In some embodiments, the metal layer 104 is formed using a suitable deposition method, such as thermal evaporation. In some other embodiments, the metal layer 104 may be formed by PVD, ALD, e-beam, CVD, or the like.

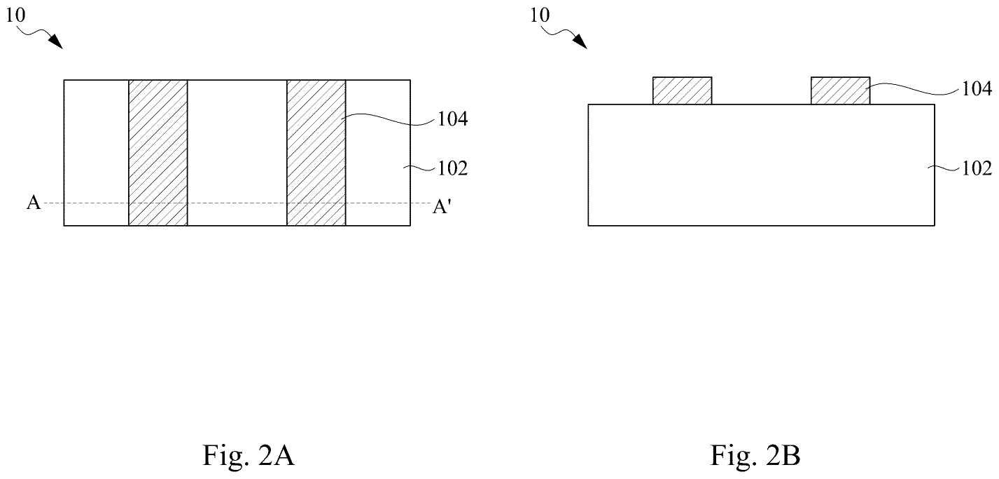

Reference is made to FIGS. 2A and 2B. In some embodiments, the metal layer 104 is then patterned by using a lithography process including a lithographic exposure step followed by a lithographic development step. In some embodiments, the metal layer 104 is patterned to form a patterned metal layer 104 covering a first portion of the 2D material layer 102, while leaving a second portion of the 2D material layer 102 exposed. For example, a photoresist layer (not shown) may be formed on the metal layer 104, and then patterned to expose a region of the metal layer 104. The exposed region of the metal layer 104 is then etched using suitable etchants by a dry etch, a wet etch, or a combination thereof such that the second portion of the 2D material layer 102 is exposed. Next, the photoresist layer is removed by a photoresist removal process, such as a stripping or an ashing process.

A position (or a pattern) of the metal layer 104 decides a position (or a pattern) of a subsequently formed oxide region. The metal layer 104 serves to catalyze an oxidation reaction of the 2D material layer 102 such that the metal layer 104 can be used to define an oxidation region in the 2D material layer 102. Stated differently, one or more oxidation regions in the 2D material layer 102 can be selectively grown by using the metal layer 104. Therefore, a controllable layout of one or more oxide regions in the 2D material layer 102 can be achieved by a layout of the metal layer 104.

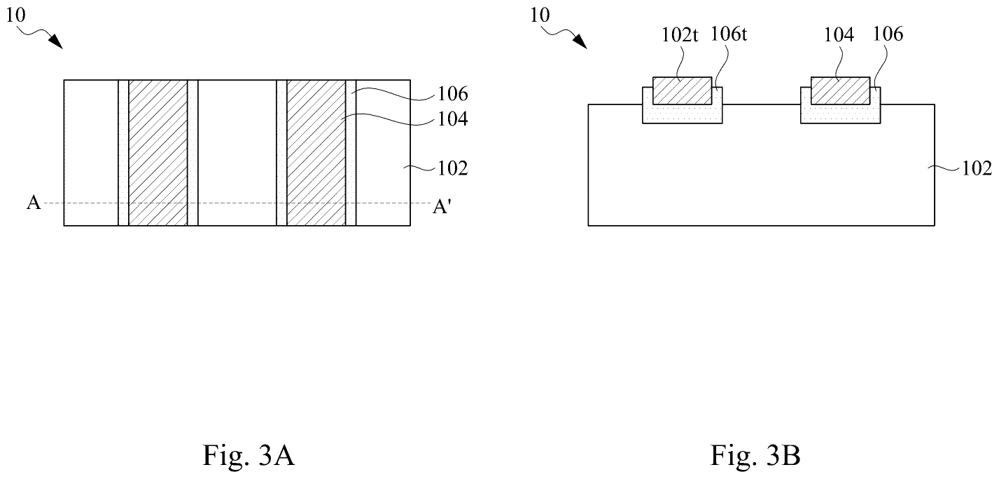

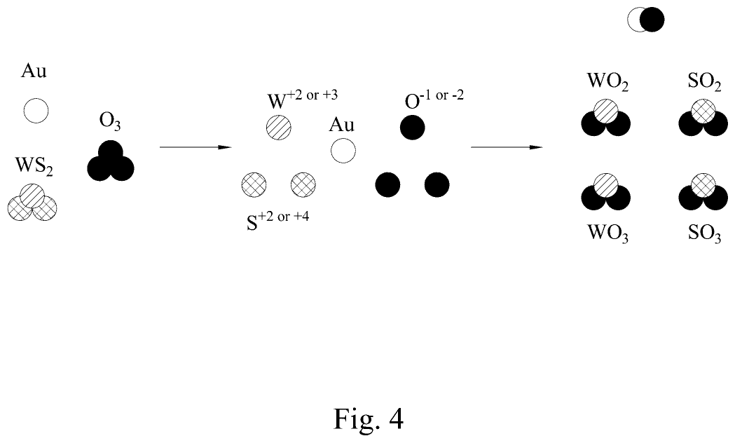

Reference is made to FIGS. 3A and 3B. An oxidation treatment is performed to the metal layer 104 and the 2D material layer 102 to form an oxide region 106. The oxide region 106 interfaces with (or in physical contact with) the 2D material layer 102. The 2D material layer 102 and the oxide region 106 may include the same transition metal, such as tungsten. For example, in some embodiments where the 2D material layer 102 is WS₂, the WS₂ is oxidized, forming the oxide region 106 including WO₂, WO₃, or a combination thereof. FIG. 4 is a schematic reaction of the oxidation treatment in accordance with some embodiments. Reference is made to FIGS. 3A, 3B and 4. In some embodiments, the 2D material layer 102 (e.g., WS₂) is oxidized by the metal layer (e.g., gold (Au)) 104 by a reaction scheme 1 shown below:

$$A \cdot {WS}_{2} + B + C \cdot {O}_{3} \to A \cdot {WO}_{x} + 2 A \cdot {SO}_{y} + B \cdot Au \cdot O \qquad Reaction scheme 1$$

In the reaction scheme 1, A, B and C are integers greater than zero, x is 2 or 3, and y is 2 or 3. At first, ozone may react with gold and be oxidize the gold, and then react with WS₂ to form WOₓ. It can be seen from the reaction scheme 1 that the metal layer (e.g., Au) 104 would directly affect a rate of the oxidation reaction. Therefore, the metal layer 104 can facilitate or catalyze the oxidation reaction of the 2D material layer 102. The “SO_{y}” in the reaction scheme 1 is a byproduct and has a gas phase.

Because the oxide region 106 is formed by oxidizing the 2D material layer 102, no additional masking and etching steps are required, and the oxide region 106 can have a uniform surface as compared to being formed by masking and etching steps. Due to the oxidation treatment being catalyzed by the metal layer 104, the oxide region 106 is formed between the metal layer 104 and the 2D material layer 102. For example, the oxidation can start from an edge of the 2D material layer 102 and occur when a thickness of the 2D material layer 102 is thin enough. Therefore, a controllable layout of the oxide region 106 can be achieved by the position (or a pattern) of the metal layer 104, as discussed above. In some embodiments, the oxide region 106 can wrap around a bottom portion of the metal layer 104 and extend above or have a top surface 106t higher than a top surface 102t of the 2D material layer 102. For example, the oxide region 106 may have a U-shape when viewed from a cross-sectional view and extend along or line opposite sidewalls 106b of the metal layer 104 when viewed from a top view.

In certain embodiments, the oxidation treatment includes an ultraviolet (UV) ozone oxidation. In some embodiments, the UV ozone oxidation is performed at a temperature in a range from about 50° C. to about 150° C., such as about 70° C. to about 130° C., such as about 80° C. for a duration in a range from about 10 minutes to about 50 minutes, such as about 10 minutes to about 30 minutes, such as about 15 minutes. By varying the temperature of the UV ozone oxidation, oxidation rates of the metal layer 104 and the 2D material layer 102 can be increased or decreased. For example, as the temperature of the UV ozone oxidation is increased, the oxidation rates of the metal layer 104 and the 2D material layer 102 can be increased. By contrast, as the temperature of the UV ozone oxidation is decreased, the oxidation rates of the metal layer 104 and the 2D material layer 102 are decreased.

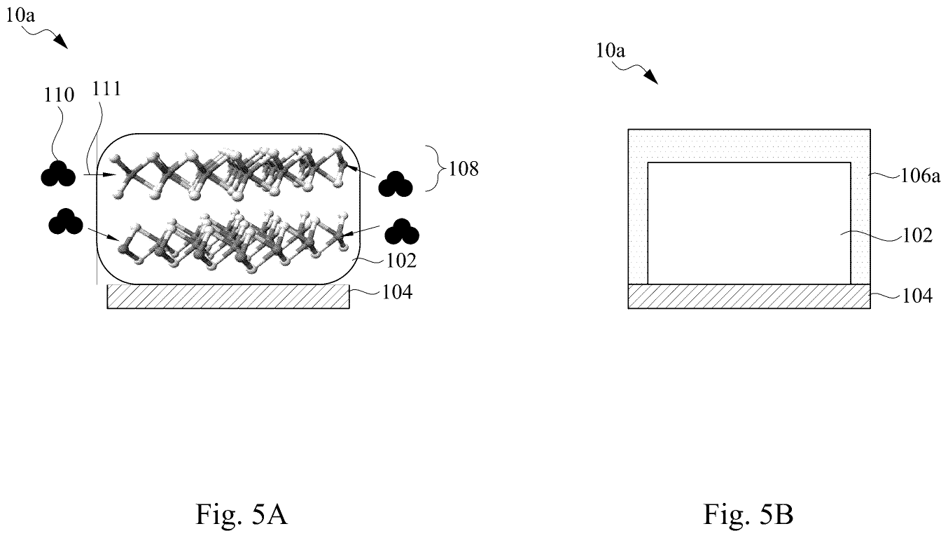

FIGS. 5A-5B are cross-sectional views of a semiconductor device 10a in various stages of fabrication in accordance with some embodiments of the present disclosure. Reference is made to FIG. 5A. A 2D material layer 102 is formed on a metal layer 104. In the 2D material layer 102, W atoms and S atoms are illustrated, and two monolayers 108 of WS₂ are shown but the present disclosure is not limited thereto. The 2D material layer 102 may include more than two monolayers of WS₂ or other 2D materials. Next, an oxidation treatment is performed to the metal layer 104 and the 2D material layer 102 using an oxygen-containing gas, such as ozone (O₃) 110 (see arrows 111).

For example, an exposed region of the 2D material layer 102 is oxidized, forming an oxide region 106a. The resulting structure is shown in FIG. 5B. Due to discontinuous bonds at edges of the 2D material layer 102, an activation energy required for the oxidation reaction is reduced at the edges of the 2D material layer 102. The oxide region 106a may cap or enclose the 2D material layer 102. In other words, the oxide region 106a extends along opposite sidewalls of the 2D material layer 102 and covers a top surface of the 2D material layer 102.

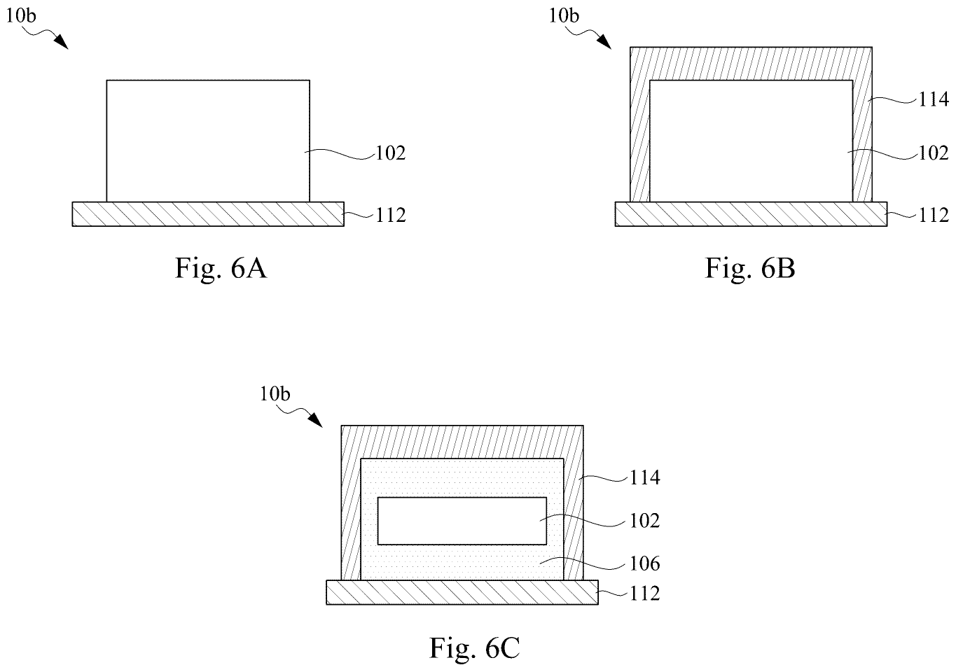

FIGS. 6A-6C are cross-sectional views of a semiconductor device 10b in various stages of fabrication in accordance with some embodiments of the present disclosure. Reference is made to FIG. 6A. In some embodiments, a bottom metal layer 112 is provided. A 2D material layer 102 is formed on the bottom metal layer 112. The bottom metal layer 112 is similar to the metal layer 104 as discussed previously with regard to FIGS. 1A-1B in terms of composition, and thus the description thereof is omitted herein. The 2D material layer 102 is similar to the 2D material layer 102 as discussed previously with regard to FIGS. 1A-1B in terms of composition and formation method, and thus the description thereof is omitted herein. For example, the 2D material layer 102 may include WS₂, and the bottom metal layer 112 may include gold.

Reference is made to FIG. 6B. A top metal layer 114 is formed over the 2D material layer 102. The top metal layer 114 is similar to the metal layer 104 as discussed previously with regard to FIGS. 1A-1B in terms of composition and formation method, and thus the description thereof is omitted herein. For example, the top metal layer 114 may include gold. The top metal layer 114 may cap the 2D material layer 102. In other words, the top metal layer 114 surrounds the 2D material layer 102 when viewed from a cross-sectional view.

Reference is made to FIG. 6C. An oxidation treatment is performed to the metal layer 104, the 2D material layer 102 and the top metal layer 114 to form an oxide region 106. The oxide region 106 wraps around or encloses the 2D material layer 102 when viewed from a cross-sectional view. For example, the oxide region 106 extends along a bottom surface, opposite sidewalls and a top surface of the 2D material layer 102. That is, the oxide region 106 interfaces with (or in physical contact with) the 2D material layer 102 at four sides of the 2D material layer 102. The oxidation treatment is similar to the oxidation treatment as discussed previously with regard to FIGS. 3A, 3B and 4. For example, the oxidation treatment includes an ultraviolet (UV) ozone oxidation. In some embodiment where the 2D material layer 102 is WS₂, the WS₂ is oxidized, forming the oxide region including WO₂, WO₃, or a combination thereof. Due to the oxidation treatment being catalyzed by the metal layer 104, the oxide region 106 is formed between the top metal layer 114 and the 2D material layer 102 and between the bottom metal layer 112 and the 2D material layer 102. In other words, the oxide region 106 may enclose the 2D material layer 102.

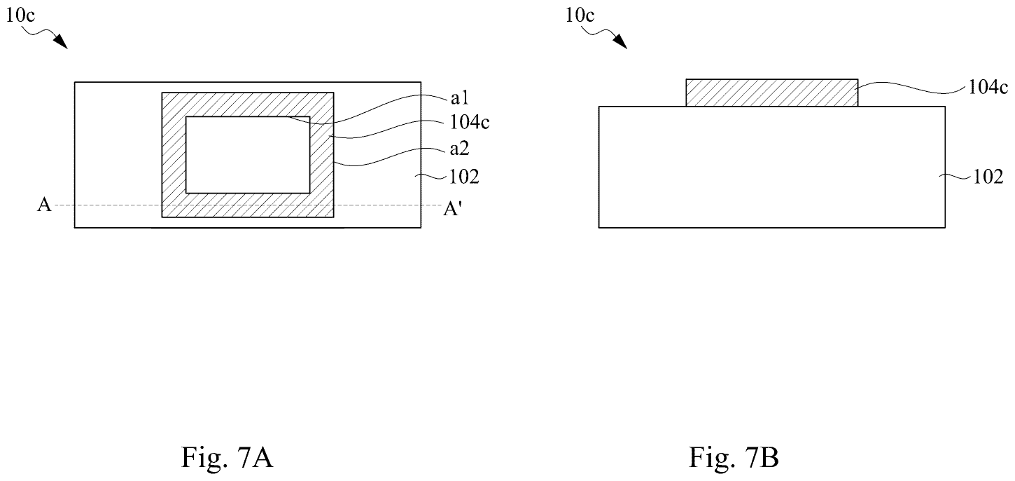

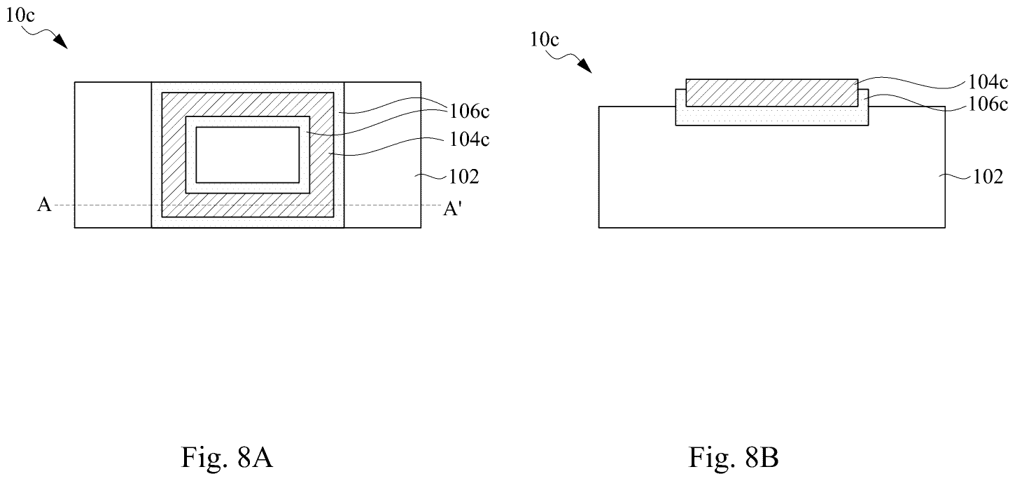

FIGS. 7A and 8A are top views of a semiconductor device 10c in various stages of fabrication in accordance with some embodiments of the present disclosure. FIGS. 7B and 8B are cross-sectional views cut along line A-A′ of FIGS. 7A and 8A, respectively. Reference is made to FIGS. 7A and 7B. A metal layer 104c is formed on a 2D material layer 102. The metal layer 104c and the 2D material layer 102 are similar to the metal layer 104 and the 2D material layer 102 as discussed previously with regard to FIGS. 1A-2B in terms of composition and formation method, except for the metal layer 104c having a hollow rectangular shape when viewed from a top view. For example, when viewed from the top view, the metal layer 104c has an inner contour a1 and an outer contour a2.

Reference is made to FIGS. 8A and 8B. An oxidation treatment is performed to the metal layer 104c and the 2D material layer 102 to form an oxide region 106c. The oxidation treatment is similar to the oxidation treatment as discussed previously with regard to FIGS. 3A, 3B and 4, and thus the detailed discussion thereof is omitted herein. Due to the oxidation treatment being catalyzed by the metal layer 104c, the oxide region 106c is formed between the metal layer 104c and the 2D material layer 102. Therefore, a controllable layout of the oxide region 106c can be achieved by the position (or a pattern) of the metal layer 104c. In some embodiments, the oxide region 106c can wrap around a bottom portion of the metal layer 104c and extend above or have a top surface higher than a top surface of the 2D material layer 102. For example, the oxide region 106c may have a U-shape when viewed from a cross-sectional view and extend along or line both of the inner contour a1 of the metal layer 104c and the outer contour a2 of the metal layer 104c when viewed from a top view.

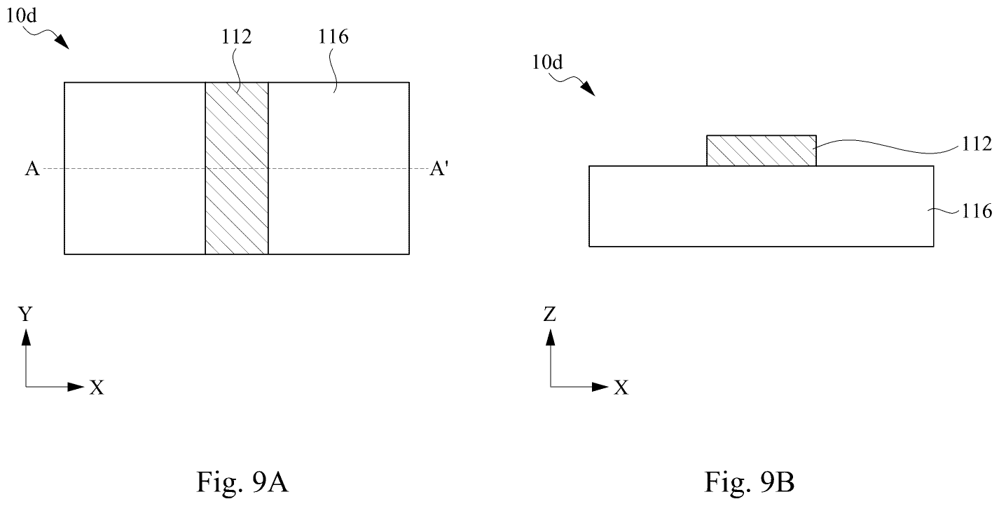

FIGS. 9A, 10A, 11A and 12A are top views of a semiconductor device 10d in various stages of fabrication in accordance with some embodiments of the present disclosure. FIGS. 9B, 10B, 11B and 12B are cross-sectional views cut along line A-A′ of FIGS. 9A, 10A, 11A and 12A, respectively. As shown, the coordinate system includes an X-axis, Y-axis, and Z-axis. Reference is made to FIGS. 9A and 9B. A bottom metal layer 112 is formed on a substrate 116. The substrate 116 may be a dielectric layer such as silicon oxide, low-k dielectric material, or other suitable dielectric materials. The bottom metal layer 112 is similar to the metal layer 104 as discussed previously with regard to FIGS. 1A-2B in terms of composition and formation method, and thus the description thereof is omitted herein. A controllable layout of a subsequently formed bottom oxide region can be achieved by a layout of the bottom metal layer 112. The bottom metal layer 112 extends along the Y-axis in some embodiments.

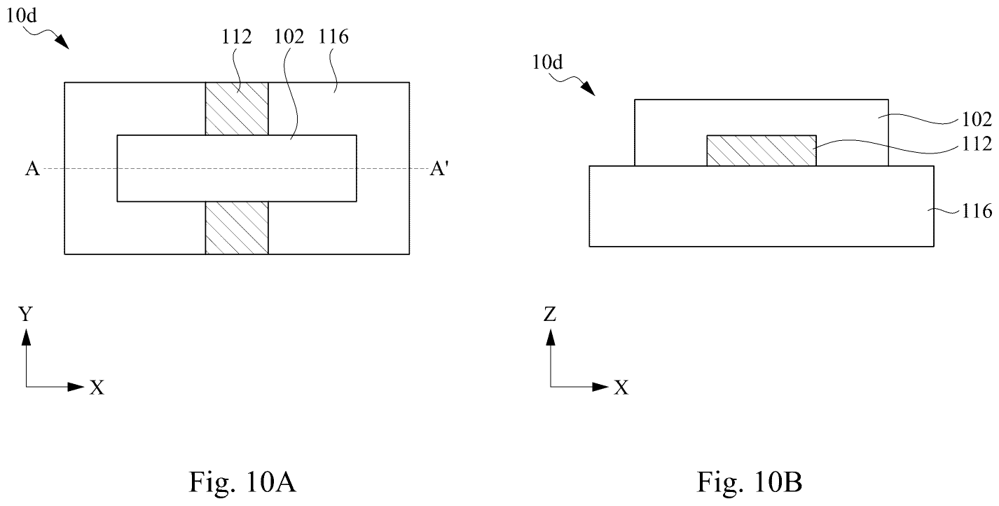

Reference is made to FIGS. 10A and 10B. A 2D material layer 102 is transferred over the bottom metal layer 112. For example, the 2D material layer 102 may be formed by micromechanical exfoliation and coupled over the substrate 116 and the bottom metal layer 112. Details of the formation method and composition of the 2D material layer 102 is similar to the formation method and the composition of the 2D material layer 102 as discussed previously with regard to FIGS. 1A-1B, and thus the description thereof is omitted herein. For example, the 2D material layer 102 may include WS₂. In some other embodiments, the 2D material layer 102 is formed by sulfurization of a pre-deposited molybdenum (Mo) film or tungsten (W) film over the substrate 116 and the bottom metal layer 112. In some embodiments, the 2D material layer may 102 extend across the bottom metal layer 112 when viewed from a top view, and the 2D material layer 102 wraps around the bottom metal layer 112 when viewed from a cross-sectional view. For example the 2D material layer 102 extends along opposite sidewalls and covers a top surface of the bottom metal layer 112 when viewed from the cross-sectional view.

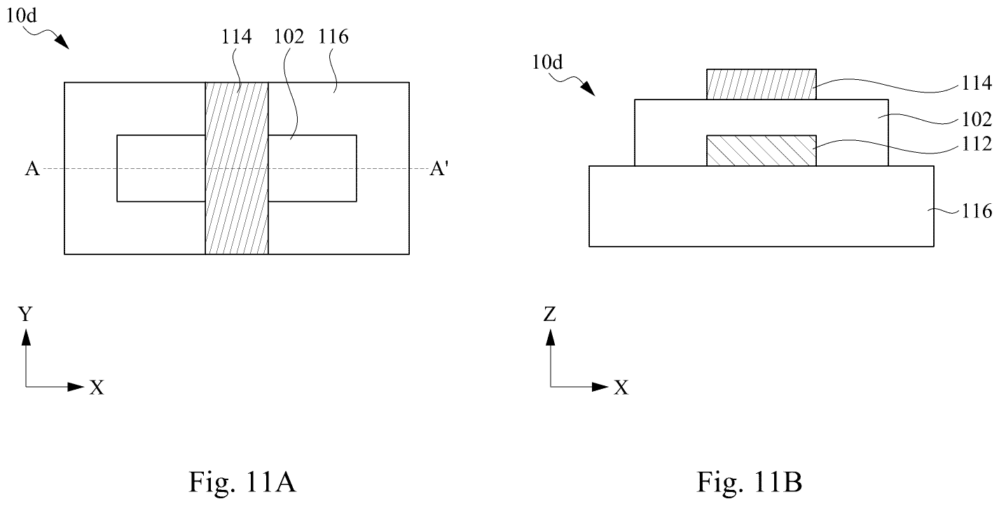

Reference is made to FIGS. 11A and 11B. A top metal layer 114 is formed over the 2D material layer 102. The top metal layer 114 is similar to the metal layer 104 as discussed previously with regard to FIGS. 1A-1B in terms of composition and formation method, and thus the description thereof is omitted herein. For example, the top metal layer 114 may include gold. The top metal layer 114 may cap the 2D material layer 102. In other words, the top metal layer 114 surrounds the 2D material layer 102 when viewed from a cross-sectional view. The top metal layer 114 extends across the 2D material layer 102 and extends along the bottom metal layer 112 when viewed from a top view. That is, an extension direction of the top metal layer 114 is parallel to an extension direction of the bottom metal layer 112. For example, the top metal layer 114 may extend along the Y-axis. A controllable layout of a subsequently formed top oxide region can be achieved by a layout of the top metal layer 114.

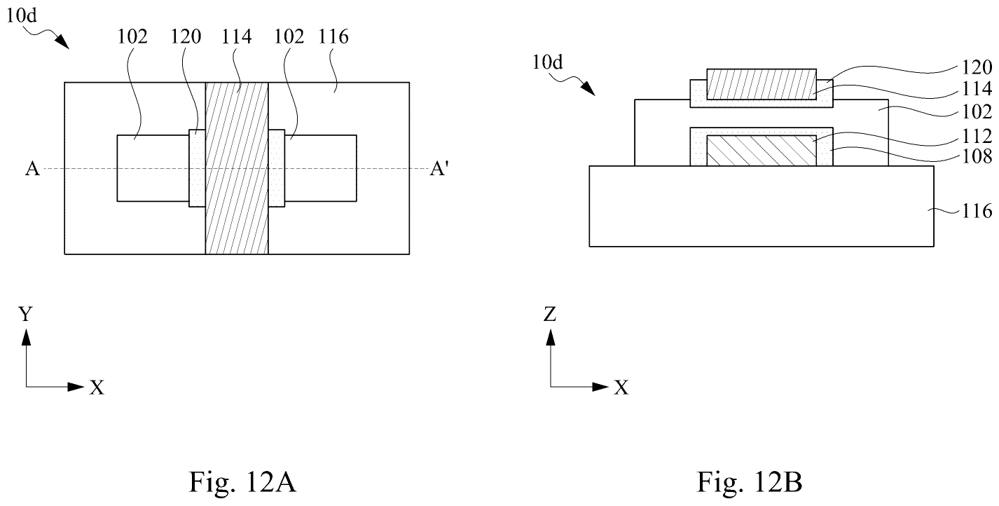

Reference is made to FIGS. 12A and 12B. An oxidation treatment is performed to the top metal layer 114, the 2D material layer 102 and the bottom metal layer 112 to form a top oxide region 120 and a bottom oxide region 118. The oxidation treatment is similar to the oxidation treatment as discussed previously with regard to FIGS. 3A, 3B and 4, and thus the detailed discussion thereof is omitted herein. Due to the oxidation treatment being catalyzed by the bottom metal layer 112, the bottom oxide region 118 is formed between the bottom metal layer 112 and the 2D material layer 102. Due to the oxidation treatment being catalyzed by the top metal layer 114, the top oxide region 120 is formed between the top metal layer 114 and the 2D material layer 102, and the bottom oxide region 118 is formed between the bottom metal layer 112 and the 2D material layer 102. In some embodiments, the top oxide region 120 can wrap around a bottom portion of the top metal layer 114 and extend above or have a top surface higher than a top surface of the 2D material layer 102. For example, the top oxide region 120 may have a U-shape when viewed from a cross-sectional view and extend along or line opposite sidewalls of the top metal layer 114 when viewed from a top view. The bottom oxide region 118 may have a U-shape when viewed from the cross-sectional view and extend along or line opposite sidewalls of the bottom metal layer 112 when viewed from a top view. The bottom oxide region 118 may wrap around the bottom metal layer 112. The top oxide region 120 interfaces with (or in physical contact with) the 2D material layer 102 and the top metal layer 114. The bottom oxide region 118 interfaces with (or in physical contact with) the 2D material layer 102 and the bottom metal layer 112. As a result, the 2D material layer 102 and the top oxide region 120 include the same transition metal, such as tungsten, and the 2D material layer 102 and the bottom oxide region 118 include the same transition metal, such as tungsten.

The 2D material layer 102 has a first portion sandwiched between the top metal layer 114 and the bottom metal layer 112 in the Z-axis and a second portion on opposite sides of the top metal layer 114 and the bottom metal layer 112. The first portion of the 2D material layer 102 functions as a channel layer of the semiconductor device 10d. The second portion of the 2D material layer 102 functions as source/drain regions of the semiconductor device 10d since a surface of the 2D material layer 102 is metallic/conductive. The semiconductor device 10d can be referred to as a gate-all-around (GAA) field effect transistor (FET). The bottom metal layer 112 and the top metal layer 114 in combination function as a gate of the semiconductor device 10d.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

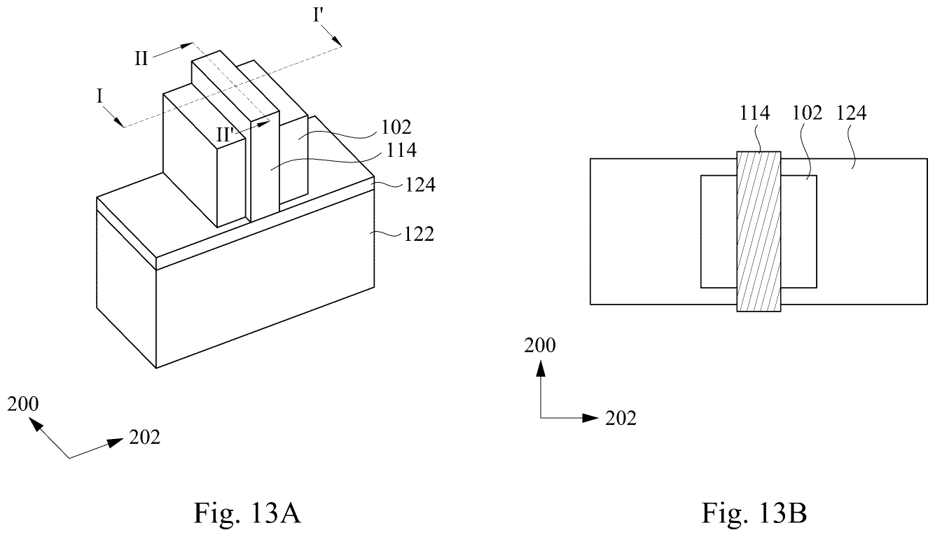

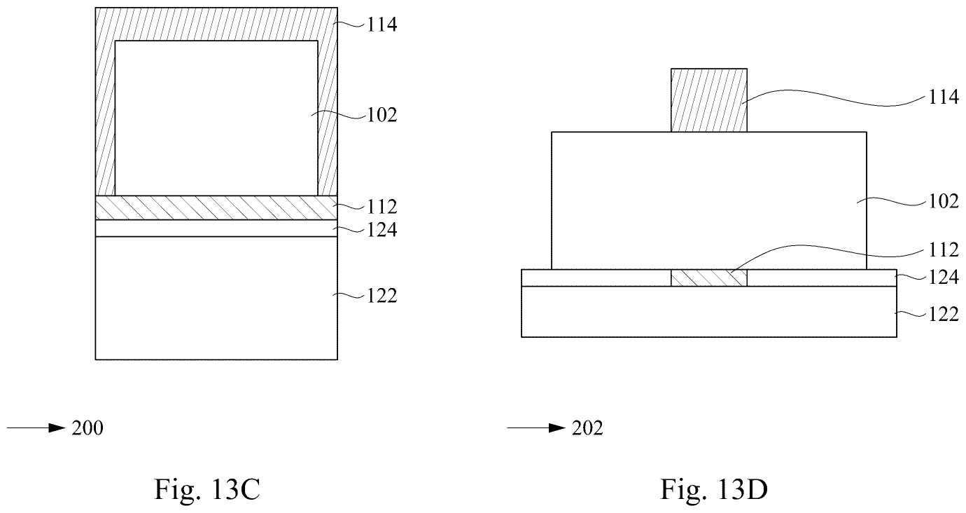

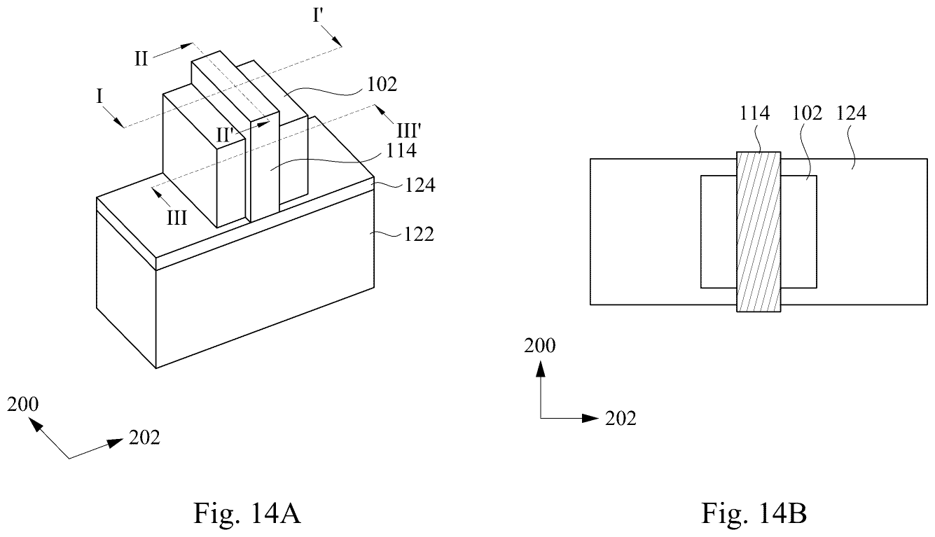

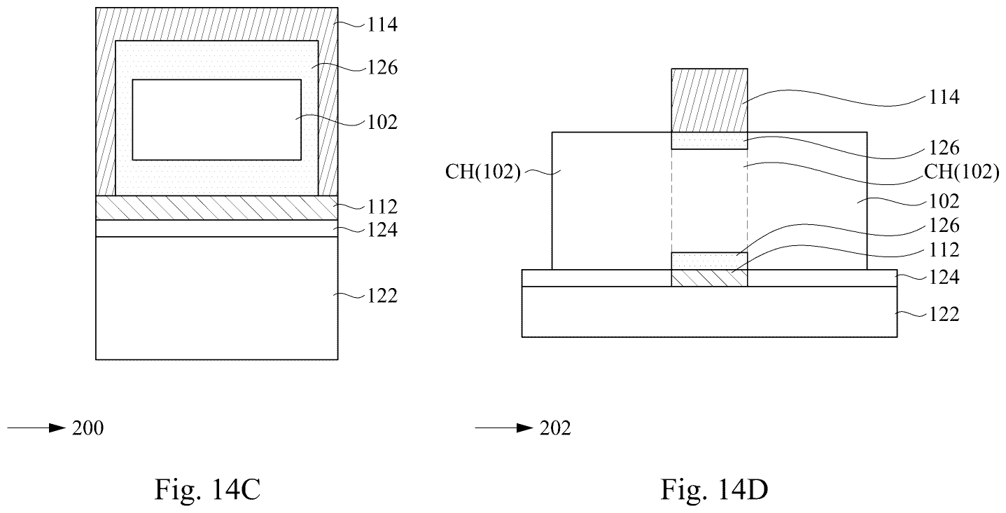

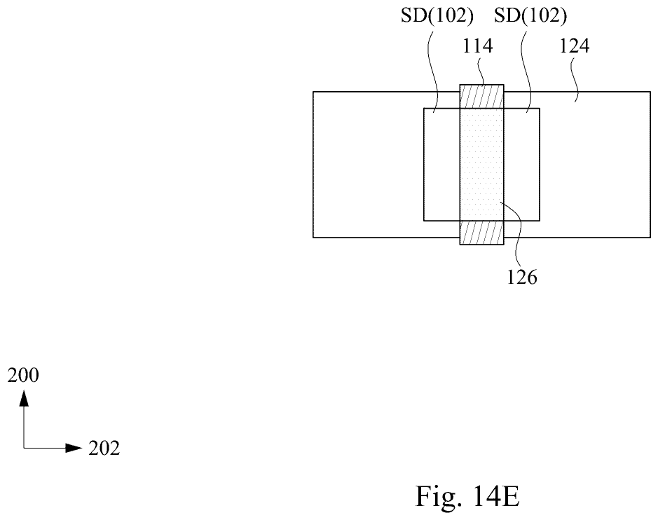

FIGS. 13A and 14A are perspective views of a semiconductor device 10e in various stages of fabrication in accordance with some embodiments of the present disclosure. FIGS. 13B and 14B are top views of the semiconductor device 10e. FIGS. 13C and 14C are cross-sectional views cutting along line II-II′ in FIGS. 13A and 14A, respectively. FIGS. 13D and 14D are cross-sectional views cutting along line I-I′ in FIGS. 13A and 14A, respectively. FIG. 14E is a top view cutting along line III-III′ in FIG. 14A. Reference is made to FIGS. 13A and 13B. A dielectric layer 124 is formed over a substrate 122 and may be formed by thermal oxidation, PVD, ALD, e-beam, CVD, or the like. The dielectric layer 124 may be silicon oxide, a low-k dielectric material, or other suitable dielectric materials. The dielectric layer 124 is then patterned by using a lithography process including a lithographic exposure step followed by a lithographic development step. For example, a photoresist layer (not shown) may be formed on the dielectric layer 124, and then patterned to form an opening (not shown) exposing the substrate 122. Next, the photoresist layer is removed by a photoresist removal process, such as a stripping or an ashing process. A bottom metal layer 112 is then formed over the dielectric layer 124, filling the opening in the dielectric layer 124 using a suitable deposition method, such as thermal evaporation. In some other embodiments, the bottom metal layer 112 may be formed by PVD, ALD, e-beam, CVD, or the like. A chemical mechanical polishing (CMP) process is performed on the bottom metal layer 112 to etch back and planarize the bottom metal layer 112 until the dielectric layer 124 is reached and exposed. As discussed previously with regard to FIGS. 2A and 2B, a position (or a pattern) of the bottom metal layer 112 can decide a position (or a pattern) of a subsequently formed oxide region. The bottom metal layer 112 is similar to the metal layer 104 in terms of composition, and thus the description thereof is omitted herein. In some embodiments, the bottom metal layer 112 extends along a first direction 200.

The substrate 122 may be a semiconductor substrate, such as a bulk semiconductor, a semiconductor-on-insulator (SOI) substrate, or the like, which may be doped (e.g., with a p-type or an n-type dopant) or undoped. The substrate 122 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 122 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A 2D material layer 102 is formed over the bottom metal layer 112 and the dielectric layer 124. The 2D material layer 102 is similar to the 2D material layer 102 with regard to FIGS. 1A and 1B in terms of composition and formation method, and thus the description thereof is omitted herein. The 2D material layer 102 interfaces with the bottom metal layer 112 and the dielectric layer 124 and extends across the bottom metal layer 112. Therefore, the 2D material layer 102 is in contact with both of the bottom metal layer 112 and the top metal layer 114. The 2D material layer 102 may extend along a second direction 202. In some embodiments, the second direction 202 is substantially perpendicular to the first direction 200.

A top metal layer 114 is formed over the 2D material layer 102 and the bottom metal layer 112 using a suitable deposition method, such as thermal evaporation. In some other embodiments, the top metal layer 114 may be formed by PVD, ALD, e-beam, CVD, or the like. The top metal layer 114 is then patterned by using a lithography process including a lithographic exposure step followed by a lithographic development step. For example, a photoresist layer (not shown) may be formed on the top metal layer 114, and then patterned to partially expose the top metal layer 114. An exposed region of the top metal layer 114 is then etched using suitable etchants by a dry etch, a wet etch, or a combination thereof. Next, the photoresist layer is removed by a photoresist removal process, such as a stripping or an ashing process.

The top metal layer 114 interfaces with the top surface of the bottom metal layer 112 and the top surface of the 2D material layer 102. In some embodiments, the top metal layer 114 extends along opposite sidewalls of the 2D material layer 102 and extends over a top surface of the 2D material layer 102 (see FIG. 13C) such that the bottom metal layer 112 and the top metal layer 114 in combination wrap a portion of the 2D material layer 102. The top metal layer 114 can decide a position (or a pattern) of a subsequently formed oxide region. The top metal layer 114 is similar to the metal layer 104 in terms of composition, and thus the description thereof is omitted herein. In some embodiments, the top metal layer 114 and the bottom metal layer 112 extend along the same direction, such as the first direction 200.

Reference is made to FIGS. 14A-14E. An oxidation treatment is performed to the bottom metal layer 112, the 2D material layer 102 and the top metal layer 114 to form an oxide region 126. The oxidation treatment is similar to the oxidation treatment as discussed previously with regard to FIGS. 3A and 3B. The 2D material layer 102 and the oxide region 126 may include the same transition metal, such as tungsten. For example, in some embodiments where the 2D material layer 102 is WS₂, the WS₂ is oxidized, forming the oxide region 126 including WO₂, WO₃, or a combination thereof. Due to the oxidation treatment being catalyzed by the bottom metal layer 112 and the top metal layer 114, the oxide region 126 is formed between the bottom metal layer 112 and the 2D material layer 102 and between the top metal layer 114 and the 2D material layer 102. As a result, the 2D material layer 102 is wrapped around by the oxide region 126 and is wrapped around by the top metal layer 114 and the bottom metal layer 112. The oxide region 126 is wrapped around by the top metal layer 114 and the bottom metal layer 112. The top metal layer 114 and the bottom metal layer 112 can be referred to as a metal gate of the semiconductor device 10e. The oxide region 126 can be referred to as a gate dielectric layer of the semiconductor device 10e.

As shown in FIG. 14D, the 2D material layer 102 has a first portion CH sandwiched between the bottom metal layer 112 and the top metal layer 114 in a vertical direction, and thus the first portion CH can be referred to as a channel layer of the semiconductor device 10e. The 2D material layer 102 has a second portion SD on opposite sides of the bottom metal layer 112 and the top metal layer 114 in which the second portion SD is connected to the first portion CH, and thus can be referred to as source/drain regions of the semiconductor device 10e. The semiconductor device 10e may be a gate-all-around (GAA) field effect transistor (FET). In FIG. 14E, a heterostructure including WOₓ (i.e., the second portion SD on the left hand side), the WOₓ (i.e., the oxide region 126) and WOₓ (i.e., the second portion SD on the right hand side) is shown.

In some embodiments, dopants may be doped into the second portion SD of the 2D material layer 102 to form a p-type or an n-type material. Dopant atoms for p-type material include boron, for example. In n-type materials, dopant atoms include phosphorous, arsenic, and antimony, for example. Doping may be done by ion implantation processes. When coupled with photolithographic processes, doping may be performed in selected areas by implanting atoms into exposed regions while other areas are masked. Also, thermal drive or anneal cycles may be used to use thermal diffusion to expand or extend a previously doped region.

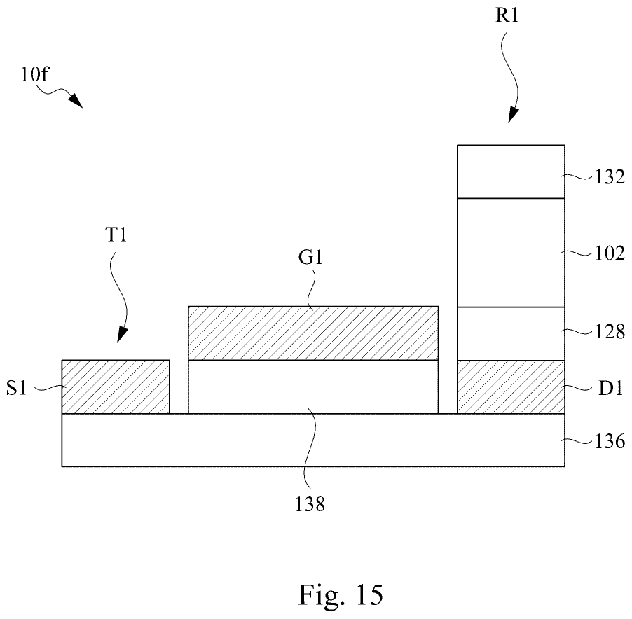

FIG. 15 is a cross-sectional view of a semiconductor device 10f in various stages of fabrication in accordance with some embodiments of the present disclosure. Reference is made to FIG. 15. The semiconductor device 10f includes a transistor T1 and a memory device R1. In some embodiments, the memory device R1 is a resistive random access memory (RRAM) device. The semiconductor device 10f may be referred to as a 1T1R device.

The transistor T1 includes a source region Si, a drain region D1, a gate G1 and an oxide layer 138 formed over the substrate 136. The memory device R1 may be formed on the drain region D1 of the transistor T1 and includes a stack including a bottom electrode 128, a 2D material layer 102, and a top electrode 132 formed over the drain region D1 of the transistor T1 in sequence. The memory device R1 may be electrically coupled to the transistor T1 through the drain region D1 of the transistor T1.

In some embodiments, the bottom electrode 128 has an electron affinity lower than an electron affinity of the top electrode 132. For example, the bottom electrode 128 is not Au, Ag, Pt, or the like, and the top electrode 132 is made of Au, Ag, Pt, or the like. In some embodiments, the bottom electrode 128 may be aluminum, aluminum alloy, copper, copper alloy, titanium, titanium nitride, tantalum, tantalum nitride, tungsten, the like, or a combination thereof.

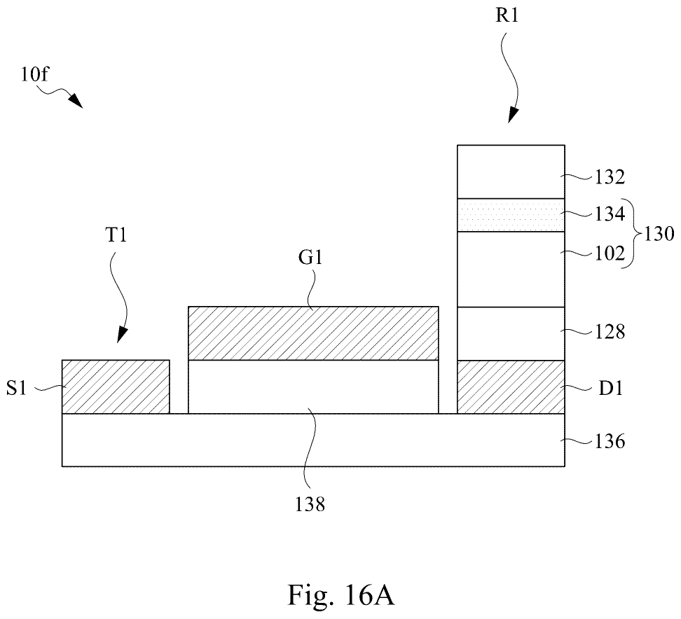

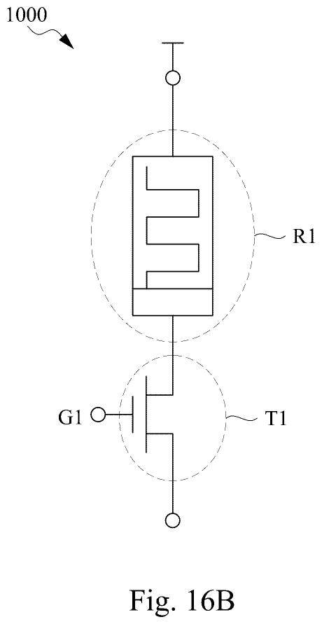

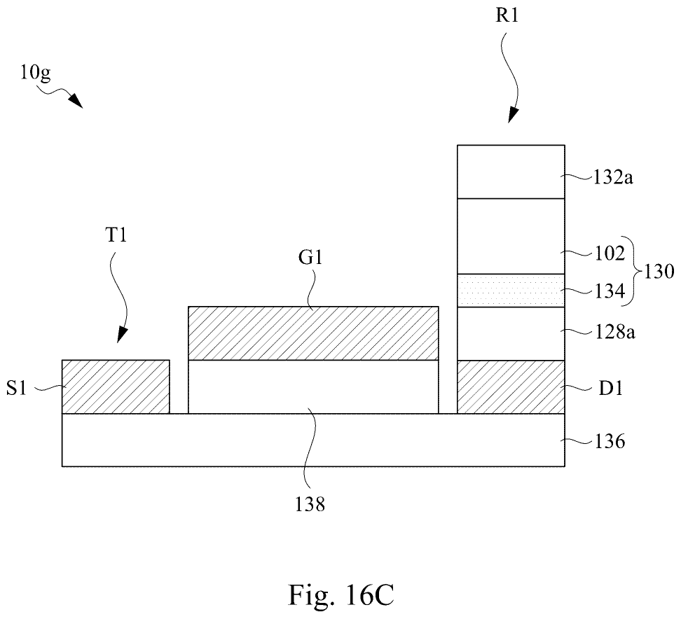

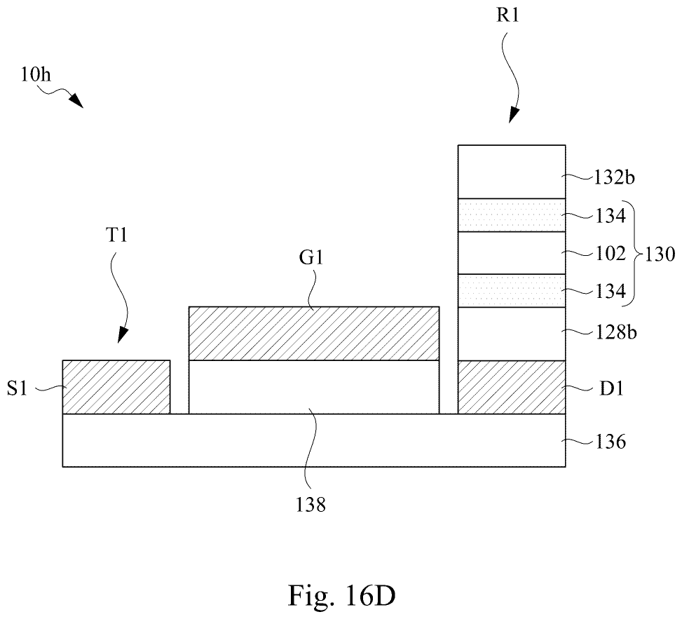

FIG. 16A is a cross-sectional view of the semiconductor device 10f in various stages of fabrication in accordance with some embodiments of the present disclosure. FIG. 16B illustrates an equivalent circuit diagram 1000 of the semiconductor device 10f illustrated in FIG. 16A. Reference is made to FIGS. 16A and 16B. An oxidation treatment is performed to the top electrode 132 and the 2D material layer 102 to form an oxide layer 134, as discussed previously with regard to FIGS. 3A-3B. The oxide layer 134 interfaces with (or in physical contact with) the 2D material layer 102 and the top electrode 132. Since the bottom electrode 128 does not have the high electron affinity, no oxide layer is formed between the bottom electrode 128 and the 2D material layer 102. The oxide layer 134 and the 2D material layer 102 in combination referred to as a dielectric layer 130 in which the oxide layer 134 is a transition metal-containing layer including a transition metal same as a transition metal of the 2D material layer 102. In other words, the dielectric layer 130 is a stack of WOₓ layer over WS₂ layer. In some other embodiments, the dielectric layer 130 may include a high-k material, for example, HfO₂, h-BN/MoS₂, the like, or a combination thereof. The dielectric layer 130 serves as a variable resistive dielectric layer or resistive switching element for operation of the memory device R1. For example, a sufficient voltage (known as a forming voltage) applied to the dielectric layer 130 will form one or more conductive pathways in the dielectric layer 130. Through the appropriate application of various voltages (e.g. a set voltage and reset voltage), the conductive pathways may be modified to form a high resistance state or a low resistance state. For example, the dielectric layer 130 may change from a first resistivity to a second resistivity upon the application of a set voltage, and from the second resistivity back to the first resistivity upon the application of a reset voltage.

The memory device R1 may be regarded as storing a logical bit, where the dielectric layer 130 has increased resistance, the memory device R1 may be regarded as storing a “0” bit; where the dielectric layer 130 has reduced resistance, the memory device R1 may be regarded as storing a “1” bit, and vice-versa. Circuitry (not shown) may be used to read the resistive state of the dielectric layer 130 by applying a read voltage to the top electrode 132 and the bottom electrode 128 and measuring the corresponding current through the dielectric layer 130. If the current through the dielectric layer 130 is greater than some predetermined baseline current, the dielectric layer 130 is deemed to be in a reduced resistance state, and therefore the memory device R1 is storing a logical “1.” On the other hand, if the current through the dielectric layer 130 is less than some predetermined baseline current, then the dielectric layer 130 is deemed to be in an increased resistance state, and therefore the memory device R1 is storing a logical “0.”

FIG. 16C is a cross-sectional view of a semiconductor device 10g in various stages of fabrication in accordance with some embodiments of the present disclosure. The semiconductor device 10g is similar to the semiconductor device 10f, except for the oxide layer 134 being between a bottom electrode 128a and the 2D material layer 102, and the materials of a top electrode 132a and the bottom electrode 128a. For example, in some embodiments, the top electrode 132a has an electron affinity lower than an electron affinity of the bottom electrode 128a. For example, the top electrode 132a is not Au, Ag, Pt, or the like, and the bottom electrode 128a is made of Au, Ag, Pt, or the like. In some embodiments, the top electrode 132a may be aluminum, aluminum alloy, copper, copper alloy, titanium, titanium nitride, tantalum, tantalum nitride, tungsten, the like, or a combination thereof.

The oxide layer 134 interfaces with (or in physical contact with) the 2D material layer 102 and the bottom electrode 128a. Since the top electrode 132a does not have the high electron affinity, no oxide layer is formed between the top electrode 132a and the 2D material layer 102. The oxide layer 134 and the 2D material layer in combination referred to as the dielectric layer 130 in which the oxide layer 134 is a transition metal-containing layer including a transition metal same as a transition metal of the 2D material layer 102. In other words, the dielectric layer 130 is a stack of WS₂ layer over WOₓ layer. In some other embodiments, the dielectric layer 130 may include a high-k material, for example, HfO₂, h-BN/MoS₂, the like, or a combination thereof.

FIG. 16D is a cross-sectional view of a semiconductor device 10h in various stages of fabrication in accordance with some embodiments of the present disclosure. The semiconductor device 10h is similar to the semiconductor device 10f, except for the oxide layer 134 being both between a bottom electrode 128b and the 2D material layer 102 and between a top electrode 132b and the 2D material layer 102, and the material of the bottom electrode 128b. For example, in some embodiments, the top electrode 132a has an electron affinity similar to an electron affinity of the bottom electrode 128a. For example, the top electrode 132b is made of Au, Ag, Pt, or the like, and the bottom electrode 128b is made of Au, Ag, Pt, or the like as well. The oxide layer 134 has a first portion interfacing with (or in physical contact with) the 2D material layer 102 and the bottom electrode 128b and a second portion interfacing with (or in physical contact with) the 2D material layer 102 and the top electrode 132b.

The oxide layer 134 and the 2D material layer 102 in combination referred to as the dielectric layer 130 in which the oxide layer 134 is a transition metal-containing layer including a transition metal same as a transition metal of the 2D material layer 102. In other words, the dielectric layer 130 is a stack of WS₂ layer sandwiched between two WOₓ layers. In some other embodiments, the dielectric layer 130 may include a high-k material, for example, HfO₂, h-BN/MoS₂, the like, or a combination thereof.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that because the oxide region is formed by oxidizing the 2D material layer, no additional masking and etching steps are required, and the oxide region can have a uniform surface as compared to being formed by masking and etching steps. Another advantage is that a controllable layout of the oxide region can be achieved by the position (or a pattern) of the metal layer.

In some embodiments, a method of forming a semiconductor device includes the following steps. A 2D material layer is formed over a bottom metal layer. A top metal layer is formed over the 2D material layer. An oxidation treatment is performed to the 2D material layer to form an oxide region interfacing both the 2D material layer and the top metal layer. In some embodiments, the oxidation treatment is performed using a UV ozone oxidation. In some embodiments, the 2D material layer is a semiconductor. In some embodiments, the 2D material layer is transition metal dichalcogenide (TMD). In some embodiments, the top metal layer is Au, Ag, Pt, or a combination thereof.

In some embodiments, a method of forming a semiconductor device includes the following steps. A metal layer is deposited over a 2D material layer. The metal layer is patterned to form a patterned metal layer covering a first portion of the 2D material layer, while leaving a second portion of the 2D material layer exposed. The first portion of the 2D material layer is selectively oxidized to form an oxidized region, while leaving at least a region of the second portion of the 2D material layer un-oxidized. In some embodiments, the oxidized region is between the metal layer and the un-oxidized region from a top view. In some embodiments, the metal layer spaced apart from the un-oxidized region. In some embodiments, the selectively oxidizing step is performed using a UV ozone oxidation. In some embodiments, the oxidized region is between the metal layer and the un-oxidized region when viewed from a cross-sectional view.

In some embodiments, a semiconductor device includes a substrate, a first metal layer, a first oxide layer, a 2D material layer, a second oxide layer and a second metal layer. The first metal layer is over the substrate. The first oxide layer is over the first metal layer. The first oxide layer wraps around the first metal layer when viewed from a cross-sectional view. The 2D material layer is over the first oxide layer and extends across the first metal layer such that the 2D material layer is on opposite sides of the first metal layer. The 2D material layer is a semiconductor. The second oxide layer is over the 2D material layer. The second metal layer is over the second oxide layer. In some embodiments, the second oxide layer interfaces with the second metal layer and the 2D material layer. In some embodiments, the first oxide layer interfaces with the 2D material layer and the first metal layer. In some embodiments, the 2D material layer and the first oxide layer comprises a same transition metal. In some embodiments, the transition metal of the 2D material layer and the first oxide layer is tungsten. In some embodiments, the 2D material layer and the second oxide layer comprises a same transition metal. In some embodiments, the transition metal of the 2D material layer and the second oxide layer is tungsten. In some embodiments, the second oxide layer has a U-shape when viewed from a cross-sectional view. In some embodiments, the second oxide layer has a top surface higher than a top surface of the second metal layer and lower than a top surface of the 2D material layer. In some embodiments, the first oxide layer is WO₂, WO₃, or a combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a 2D material layer over a bottom metal layer;
forming a top metal layer over the 2D material layer; and
performing an oxidation treatment to the 2D material layer, to form an oxide region interfacing both the 2D material layer and the top metal layer.

2. The method of claim 1, wherein the oxidation treatment is performed using a UV ozone oxidation.

3. The method of claim 1, wherein the 2D material layer is a semiconductor.

4. The method of claim 1, wherein the 2D material layer is transition metal dichalcogenide (TMD).

5. The method of claim 1, wherein the top metal layer is Au, Ag, Pt, or a combination thereof.

6. A method of forming a semiconductor device, comprising:
depositing a metal layer over a 2D material layer;
patterning the metal layer to form a patterned metal layer covering a first portion of the 2D material layer, while leaving a second portion of the 2D material layer exposed; and
selectively oxidizing the first portion of the 2D material layer to form an oxidized region, while leaving at least a region of the second portion of the 2D material layer un-oxidized.

7. The method of claim 6, wherein the oxidized region is between the metal layer and the un-oxidized region from a top view.

8. The method of claim 6, wherein the metal layer spaced apart from the un-oxidized region.

9. The method of claim 6, wherein the selectively oxidizing step is performed using a UV ozone oxidation.

10. The method of claim 6, wherein the oxidized region is between the metal layer and the un-oxidized region when viewed from a cross-sectional view.

11. A semiconductor device, comprising:
a substrate;
a first metal layer over the substrate;
a first oxide layer over the first metal layer, wherein the first oxide layer wraps around the first metal layer when viewed from a cross-sectional view;
a 2D material layer over the first oxide layer and extending across the first metal layer such that the 2D material layer is on opposite sides of the first metal layer, wherein the 2D material layer is a semiconductor;
a second oxide layer over the 2D material layer; and
a second metal layer over the second oxide layer.

12. The semiconductor device of claim 11, wherein the second oxide layer interfaces with the second metal layer and the 2D material layer.

13. The semiconductor device of claim 11, wherein the first oxide layer interfaces with the 2D material layer and the first metal layer.

14. The semiconductor device of claim 11, wherein the 2D material layer and the first oxide layer comprises a same transition metal.

15. The semiconductor device of claim 14, wherein the transition metal of the 2D material layer and the first oxide layer is tungsten.

16. The semiconductor device of claim 11, wherein the 2D material layer and the second oxide layer comprises a same transition metal.

17. The semiconductor device of claim 16, wherein the transition metal of the 2D material layer and the second oxide layer is tungsten.

18. The semiconductor device of claim 11, wherein the second oxide layer has a U-shape when viewed from a cross-sectional view.

19. The semiconductor device of claim 11, wherein the second oxide layer has a top surface higher than a top surface of the second metal layer and lower than a top surface of the 2D material layer.

20. The semiconductor device of claim 11, wherein the first oxide layer is WO₂, WO₃, or a combination thereof.
